(19) United States
(12) Patent Application Publication
(10) Pub. No.: US 2009/0004851 A1
(43) Pub. Date: Jan. 1, 2009

(54) SALICIDATION PROCESS USING ELECTROLESS PLATING TO DEPOSIT METAL AND INTRODUCE DOPANT IMPURITIES

(75) Inventors: Shau-Lin Shue, Hsinchu (TW); Ting-Chu Ko, Hsinchu (TW); Chien-Hsueh Shih, Taipei (TW)

Correspondence Address: DUANE MORRIS LLP (TSMC);IP DEPARTMENT, 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/770,817

(22) Filed: Jun. 29, 2007

(51) Int. Cl. H01L 21/02

(52) U.S. Cl. 438/660; 257/E21.175

(57) ABSTRACT

A selective electroless plating operation provides for the selective deposition of a metal film only on exposed silicon surfaces of a semiconductor substrate and not on other surfaces such as dielectric surfaces. The plating solution includes metal ions and advantageously also includes dopant impurity ions. The pure metal or metal alloy film formed on the exposed silicon surfaces is then heat treated to form a metal silicide on the exposed silicon surfaces and to drive the dopant impurities to the interface formed between the exposed silicon surfaces and the metal silicide film.

### FIELD OF THE INVENTION

The present invention relates, most generally, to semiconductor devices and methods for forming the same. In particular, the present invention is directed to the selective electroless deposition of metal materials on exposed silicon surfaces.

### BACKGROUND

In advanced semiconductor device processing, metal silicide films are formed on silicon surfaces to improve device speed and contact resistance for contact made to the silicon surface. Contact resistance is lowered when an interconnect material contacts a metal silicide film formed on a silicon surface, in comparison to the interconnect material directly contacting the silicon surface.

According to conventional processing technology, metal silicide layers are formed over exposed silicon surfaces on a semiconductor device by depositing a metal film over the entire surface of a semiconductor substrate, including over exposed silicon sections and over other sections such as dielectric sections. After the metal film is formed over the entire substrate surface, a heating operation is carried out to cause reaction between the deposited metal film and the exposed silicon surfaces in areas where the deposited metal film contacts the silicon surfaces. In other areas, such as where the deposited metal film is disposed over a dielectric, no reaction occurs. After the metal silicide layer is formed by reaction between metal from the metal film and silicon from the silicon surface, the un-reacted portions of the deposited metal layer are then removed. The un-reacted portions of the deposited metal layer can be removed using a selective etching process or other suitable processes. After the unwanted and un-reacted metal is removed, a further heating process is often used to obtain the desired phase of the metal silicide. Nickel, Ni, and Cobalt, Co, are metal materials that are commonly used in this application.

A shortcoming of the aforedescribed conventional processing sequence is that the selective etching process or other process used to remove the un-reacted, deposited metal, generates particle contamination that can result in electrical, yield and device performance degradation. It would be therefore desirable to form suitable metal silicide layers in desired locations without generating contaminating particles.

### SUMMARY OF THE INVENTION

To address these and other needs, and in view of its purposes, the present invention provides, in one aspect, a method for forming a semiconductor device. The method includes providing a semiconductor substrate with a semiconductor device thereon, the semiconductor device having exposed silicon surfaces and exposed dielectric surfaces. The method further includes positioning the semiconductor substrate in an electroless plating solution that includes at least metal ions therein. The method provides for urging the metal ions to selectively deposit only on the exposed silicon surfaces and not on the dielectric surfaces, thereby forming a metal film on the exposed silicon surfaces.

According to another aspect, the invention provides a method for forming a semiconductor device, the method including providing a semiconductor substrate with a semiconductor device thereon, the semiconductor device having exposed silicon surfaces and exposed dielectric surfaces. The semiconductor substrate is positioned in an electroless plating solution that includes at least metal ions and dopant impurity ions therein. The method provides for urging the metal ions to selectively deposit only on the exposed silicon surfaces and not on the dielectric surfaces, thereby forming a metal film on the exposed metal surfaces. The method further provides for heating to form a metal silicide by causing the metal film to react with silicon from the exposed silicon surfaces, the heating also causing the dopant impurity ions to become situated at an interface between the exposed silicon surfaces and the metal silicide.

According to another aspect, the invention provides a method for forming a semiconductor device which includes providing a semiconductor substrate with a semiconductor device thereon, the semiconductor device having at least exposed silicon surfaces. The method provides for positioning the semiconductor substrate in an electroless plating solution that includes at least metal ions and dopant impurity ions therein, controlling conditions of the electroless plating solution to cause formation of a metal layer formed of the metal ions. The metal layer is formed on the silicon surface and the metal layer includes the dopant impurity ions therein. The method further provides for heating to cause reaction between the metal layer and the exposed silicon surfaces to form a metal silicide film and the heating further causes the dopant impurity ions to become institiated at an interface formed between the metal silicide film and the exposed silicon surfaces.

### BRIEF DESCRIPTION OF THE DRAINING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

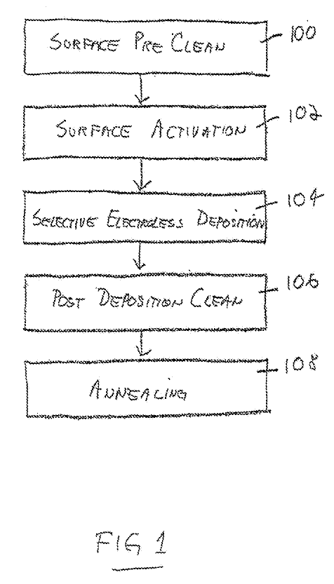

FIG. 1 is a flow chart showing an exemplary silicidation process using electroless plating to deposit metal and introduce dopant impurities; and

FIGS. 2-4 are cross-sectional views showing an exemplary sequence of processing operations used to form a self-aligned metal silicide film according to the invention.

### DETAILED DESCRIPTION

The process for forming metal silicide layers by selective electroless deposition of metal materials on exposed silicon surfaces of semiconductor devices, is shown in most general form in FIG. 1. FIG. 1 is a flow chart that illustrates the processing sequence of surface pre-clean (step 100); surface activation (step 102); selective electro less deposition (step 104); post-deposition clean (step 106); and annealing (step 108). These processing operation steps are discussed in further detail below, in conjunction with FIGS. 2-4 which illustrate the semiconductor substrate being processed. The metal silicide layer is formed directly on exposed silicon surfaces. A seed layer is not required. A consumable masking layer is not required.

FIG. 2 is a cross-sectional view showing an exemplary portion of a semiconductor device upon which the method of the invention may be practiced. FIG. 2 illustrates substrate 2 with substrate surface 4. Dielectric portion 6 and silicon film 8 are formed over substrate surface 4 in the illustrated embodiment. Silicon film 8 may be doped or undoped and it may consist of polycrystalline silicon, crystalline silicon, or amorphous silicon. Substrate 2 may be formed of various suitable semiconductor materials and in the illustrated embodiment, includes exposed substrate surfaces 10. According to the exemplary embodiment in which substrate 2 is formed of silicon, the exposed substrate surfaces 10 will be exposed silicon surfaces 10 as will be referred to hereinafter, Silicon film 8 includes exposed silicon surface 12. As such, the illustrated embodiment includes exposed silicon surfaces 10 and 12 which represent exposed portions of substrate 2 and silicon film 8, respectively. The invention is not, however, limited to utilizing a silicon substrate and in other exemplary embodiments, the exposed silicon surfaces may consist only of silicon surfaces of silicon features formed in and/or over the semiconductor substrate. As such, it should be understood that the structure shown in FIG. 2 is exemplary only and is presented to illustrate the selective deposition of metal on exposed silicon surfaces but not on dielectric materials. It should be understood that, in practice, there may be several different regions of exposed silicon surfaces that may represent exposed portions of silicon structures formed at various topological levels within the device. For example, a silicon layer with an exposed silicon surface may be formed to step over various device structures. Dielectric portion 6, although illustrated as a film formed over substrate 2 in the illustrated embodiment, may represent an STI, shallow trench isolation, oxide, spacers, and RPO, resist protect oxide, or various other dielectric structures. Dielectric portion 6 represents any suitable dielectric material that may be formed in or on the semiconductor substrate including but not limited to oxides, nitrides, low-k dielectric materials, high-k dielectric materials, and the like.

The structure shown in FIG. 2 may advantageously have a metal film selectively deposited only on exposed silicon surfaces 10, 12 thereof according to the invention. Seed layers or consumable masking layers are not needed.

The structure shown in FIG. 2 may advantageously be pre-cleaned prior to selective metal deposition. According to various exemplary embodiments, a 0.5-1% dilute acidic solution may be used for a wet, surface pre-clean (step 100). Suitable acids for the optional pre-cleaning step include citric acid, HF, sulfuric acid, and methane sulfuric acid, but other suitable dilute acidic solutions may be used in other exemplary embodiments. In some exemplary embodiments, the surface pre-clean may not be utilized, and in other exemplary embodiments, plasma or other pre-cleans may be used.

After the optional pre-clean, a surface activation step (step 102) may be carried out. The surface activation operation is again a wet processing operation and may include exposing the structure shown in FIG. 2, to Pd nanoparticles, Pd²⁺, Pt²⁺ or various other suitable species used for surface activation. The surface activation species may alternatively or additionally be included within the electroless deposition solution described below.

After the surface activation operation, the structure shown in FIG. 2 is then disposed within an electroless deposition solution that will have its parameters controlled to effectuate the deposition of a metal film only on exposed silicon surfaces but not on dielectric or other surfaces (step 104). Most generally, the electroless solution includes a metal salt, a reducing agent, a complexing agent, a buffering agent, a wetting agent and optionally a surface activation agent. The metal may be nickel, cobalt, platinum, molybdenum, titanium, ytterbium, erbium or other materials suitably used to form metal silicide films on semiconductor devices. According to exemplary embodiments in which nickel is the metal, NiSO₄ or NiCl₂ may be the salt used as the source of nickel. It should be understood that the foregoing sources are exemplary only and other salts may be used as the source of nickel in other exemplary embodiments. Various suitable sources for Co, Pt, Ti, Yb and Er may be used. Exemplary reducing agents include hypophosphite and dimtethylamine borane, DMAB. An exemplary complexing agent is citrate, Na₃C₆H₅O₇.2H₂O but other complexing agents may be used in other exemplary embodiments, Suitable buffering agents include NH₃OH and NaOH and polyethylene glycol may be used as a suitable wetting agent. The foregoing components are intended to be exemplary and not limiting of the electroless plating solution.

In addition to the metal ions produced by the dissolution of the metal salt, dopant impurity ions such as B, P and W may also be included in the electroless deposition solution. According to an exemplary embodiment in which n-type dopant impurity boron, B, is the dopant impurity, the boron may be provided in the electroless deposition solution by using the DMAB reducing agent and according to an exemplary embodiment in which a p-type dopant impurity ion is desired, hypophosphite may be used as the reducing agent and as a source of phosphorous, P. Other boron and phosphorus sources may be used in other exemplary embodiments. According to yet another exemplary embodiment, tungstate, WO₄, may be used as a tungsten, W, source to provide thermal stability during and after the subsequent silicidation process.

Key parameters are controlled to urge electroless deposition of a metal film selectively upon exposed silicon surfaces but not on dielectric surfaces. Key parameters may include temperature, pH, concentration of the metal ions, and concentration of the reducing agent in the solution. In one exemplary embodiment, the temperature may be advantageously maintained between about 40 to 90° C., the pH maintained between about 4-9 and the metal salt concentration maintained between about 0.05M-5M (mole/L). The reducing agent concentration may advantageously be maintained within a concentration of about 0.01M (mole/L)-1M (mole/L). Various conventional techniques and methods may be used to monitor the key parameters and control the same. In one exemplary embodiment, the pH may be maintained within about 8.5-10 and the deposition temperature between about 70 and 80° C. By controlling the key parameters to produce an electroless deposition solution with a desired combination of parameters, a metal film will form only on exposed silicon surfaces 10, 12 shown in FIG. 2.

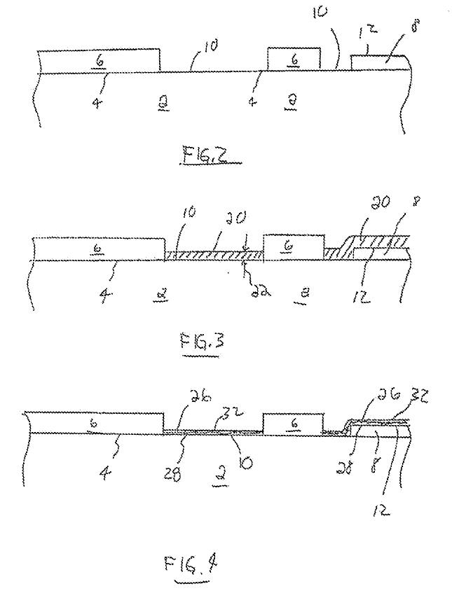

The parameters of the electroless plating solution are controlled such that a metal film consisting of the metal ions from the electroless plating solution deposit on exposed silicon surfaces such as exposed silicon surfaces 10, 12 shown in FIG. 2. Now referring to FIG. 3, metal film 20 is formed on exposed silicon surfaces 10, 12. Metal film 20 may be nickel, cobalt, platinum or other suitable metal materials such as titanium, Ti, platinum, Pt, ytterbium, Yb, molybdenum, Mo, or erbium, Er. FIG. 3 illustrates that metal film 20 is selectively deposited and is not deposited upon the surfaces of dielectric portions 6. The deposition rate may range from about 20-200 angstroms/minute according to one exemplary embodiment but other deposition rates may be achieved in other exemplary embodiments and depend upon the key parameters mentioned above. Metal film 20 may be deposited to include thickness 22 which may range from 10 to 300 angstroms according to one exemplary embodiment but thickness 22 may take on other values according to other exemplary embodiments. Metal film 20 may be a pure metal film according to embodiments in which no dopant impurity ions are included in the electroless plating solution and in other exemplary embodiments, metal film 20 may be an alloy consisting of about 95% of a metal such as nickel, platinum, erbium, ytterbium, cobalt or molybdenum and also including one or more additives/impurity ions such as P, B, W, and the like.

After the deposition of metal film 20, and prior to any subsequent heating operations, and optional pos-deposition clean (step 106) may be carried out. The post-deposition clean may be carried out using a brush or other similar physical cleaning operation or it may be a clean carried out using a dilute acid clean similar to one of the pre-cleaning dilute acid cleaning operations described above.

The structure in FIG. 3 is then heated (step 108) to form the structure shown in FIG. 4.

FIG. 4 shows metal silicide layer 26 formed on exposed silicon surfaces 10, 12. Metal silicide layer 26 is formed by the reaction between metal from the metal layer 20 shown in FIG. 3 and silicon from the exposed silicon surfaces 10, 12. The original silicon surfaces may be partially receded as the metal silicide layer 26 is formed, i.e. metal silicide layer 26 may form at the expense of the upper silicon layer of exposed silicon surfaces. A conventional annealing process may be used in one exemplary embodiment and multiple conventional annealing processes may be used in another exemplary embodiment. Each annealing process may be a furnace operation or it may be a rapid thermal anneal, RTA, process. In one exemplary embodiment, two annealing processes may be carried out; the first annealing process forms metal silicide film 26 such as shown in FIG. 4 and the second annealing operation produces a particular desired silicide phase. Nickel silicide, for example, may include several phases such as Ni₂Si, NiSi₂, NiSi, and other stoichiometric ratios. Various suitable temperatures and times may be used depending on the phase desired, the thickness of the metal film as deposited and other factors. The presence of W as a dopant impurity helps to lower the thermal budget and allows for the formation of a thermally stable silicide phase.

During either or both of the annealing operations, the dopant impurity ions such as B, P, etc., are driven to interface 28 formed between exposed silicon surfaces 10, 12 and silicide film 26. The presence of boron or phosphorus at interface 28 aids in lowering contact resistance to the metal silicide film 26. When tungsten is used as an impurity ion in metal silicide film 26, it serves to provide enhanced thermal stability and enables formation of the desired silicide phase with a restricted thermal budget.

The structure shown in FIG. 4, is then further processed according to various suitable semiconductor fabrication operations to form further structures and completed semiconductor devices. In particular, when conductive interconnection layers are brought to contact surface 32 of metal silicide film 26, a desirably lowered contact resistance is achieved. Processes to remove excess, unreacted metal are not needed.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal, “vertical,” above,” “below,” “up,” “down,” “tops” and “bottom” as well as derivatives thereof (e.g., “horizontally,” “downwardly,” “upwardly,” etc.) should be construed to refer to the orientation as then described or as shown in the drawing under discussion These relative terms are for convenience of description and do not require that the apparatus be constructed or operated in a particular orientation.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for forming a semiconductor device comprising:
providing a semiconductor substrate with a semiconductor device thereon, said semiconductor device having exposed silicon surfaces and exposed dielectric surfaces;
positioning said semiconductor substrate in an electroless plating solution that includes at least metal ions therein, and
urging a metal film of said metal ions to selectively deposit only on said exposed silicon surfaces and not on said dielectric surfaces.

2. The method as in claim 1, wherein said electroless plating solution further includes at least one dopant impurity therein, and wherein said metal film is an alloy including said at least one dopant impurity as a component thereof.

3. The method as in claim 2, wherein said dopant impurity comprises boron and further comprising:
heating to cause silicon from said exposed silicon surfaces to react with said metal film to form a metal silicide and to cause said boron to become situated at an interface between said exposed silicon surfaces and said metal silicide, said heating taking place after said urging.

4. The method as in claim 2, wherein said dopant impurity comprises phosphorus and further comprising:
heating to cause silicon from said exposed silicon surfaces to react with said metal film to form a metal silicide and to cause said phosphorus to become situated at an interface between said exposed silicon surfaces and said metal silicide, said heating taking place after said urging.

5. The method as in claim 2, wherein said dopant comprises tungsten.

6. The method as in claim 1, wherein said metal ions comprise nickel and further comprising, after said urging, heating to form NiSi on said exposed silicon surfaces.

7. The method as in claim 1, wherein said urging comprises controlling temperature, pH and chemical concentration of said electroless plating solution.

8. The method as in claim 1, wherein said urging comprises maintaining said electroless plating solution to have a temperature within a range of about 40-90° C., a pH between about 4 and 9, and a concentration of said metal ions between about 0.05M (mole/L)-5M (mole/L).

9. The method as in claim 1, further comprising heating to form a metal silicide through combination of said metal film and said exposed silicon surfaces.

10. The method as in claim 9, further comprising further heating to change phase of said metal silicide.

11. The method as in claim 9, wherein said heating takes place directly following said urging.

12. The method as in claim 1, wherein said electroless plating solution further comprises a reducing agent at a concentration ranging between about 0.01M (mole/L) to about 1.0M (mole/L).

13. The method as in claim 1, further comprising carrying out a surface activation step after said providing and prior to said positioning, said surface activation step comprising a vet process including at least one of Pd²⁺, Pd nanoparticles, and Pt²⁺ as surface activators therein.

14. The method as in claim 1, wherein said metal film is deposited on said exposed silicon surfaces at a metal deposition rate within the range of about 20-200 A/min.

15. The method as in claim 1, wherein said metal ions comprise cobalt and further comprising, after said urging, heating to form CoSi on said exposed silicon surfaces.

16. The method as in claim 1, wherein said metal ions comprise one of titanium, platinum, molybdenum, ytterbium and erbium.

17. A method for forming a semiconductor device comprising:
providing a semiconductor substrate with a semiconductor device thereon, said semiconductor device having exposed silicon surfaces and exposed dielectric surfaces;
positioning said semiconductor substrate in an electroless plating solution that includes at least metal ions and dopant impurity ions therein;
urging said metal ions to selectively deposit only on said exposed silicon surfaces and not on said dielectric surfaces thereby forming a metal film only on said exposed silicon surfaces; and
heating to form a metal silicide by causing said metal film to react with silicon from said exposed silicon surfaces and causing said dopant impurity ions to become situated at an interface between said exposed silicon surfaces and said metal silicide.

18. The method as in claim 17, wherein said urging comprises controlling temperature, pH and chemical concentration of said electroless plating solution and further comprising further heating to cause a phase change of said metal silicide.

19. A method for forming a semiconductor device comprising:
providing a semiconductor substrate with a semiconductor device thereon, said semiconductor device having at least exposed silicon surfaces;
positioning said semiconductor substrate in an electroless plating solution that includes at least metal ions and dopant impurity ions therein;
controlling conditions of said electroless plating solution to cause formation of a metal layer formed of said metal ions, on said silicon surface, said metal layer including said dopant impurity ions therein; and
heating to cause reaction between said metal layer and said exposed silicon surfaces, thus forming a metal silicide film and further causing said dopant impurity ions to become institiated at an interface formed between said metal silicide film and said exposed silicon surfaces.

20. The method as in claim 19, wherein said electroless plating solution includes a nickel salt, hydrophosphite or dimethylamine borane as a reducing agent, citrate as a complexing agent, NH₃H and NaOH as a buffering agent and polyethylene glycol as a wetting agent.
